(19) United States
(12) Patent Application Publication
(10) Pub. No.: US 2015/0276881 A1
(43) Pub. Date: Oct. 1, 2015

(54) MODEL-INDEPENDENT BATTERY LIFE AND PERFORMANCE FORECASTER

(71) Applicant: The Boeing Company, Chicago, IL (US)

(72) Inventors: Shengyi Liu, Sammamish, WA (US); Lijun Gao, Renton, WA (US)

(73) Assignee: The Boeing Company, Chicago, IL (US)

(21) Appl. No.: 14/224,902

(22) Filed: Mar. 25, 2014

(51) Int. Cl. G01R 31/36; H02J 7/00

(52) U.S. Cl. CPC G01R 31/3606; G01R 31/3648; H02J 7/0047

(57) ABSTRACT

A method includes determining parameters of a rechargeable battery during an effective power cycle of the rechargeable battery. The parameters include a current provided by the rechargeable battery, a voltage across the rechargeable battery, and a temperature of the rechargeable battery. The effective power cycle includes multiple charge operations and multiple discharge operations. The method includes estimating a remaining capacity of the rechargeable battery based on the current, the voltage, and the temperature. The method also includes generating an output indicating the remaining capacity.

### FIELD OF THE DISCLOSURE

The present disclosure relates to estimating parameters indicating battery life and performance of a rechargeable battery.

### BACKGROUND

Rechargeable batteries are used to supply power to a wide variety of devices. During a lifetime of a rechargeable battery, performance of the rechargeable battery may degrade as materials capable of holding an electric charge are lost. This is known as an “aging effect.” Performance of the rechargeable battery may be monitored by monitoring parameters of the rechargeable battery, such as capacity and internal resistance. Capacity refers to an amount of electric charge stored in the rechargeable battery when the rechargeable battery is fully charged. Internal resistance refers to an equivalent series resistance of the rechargeable battery. The capacity and internal resistance may be measured, but such measurements are time-consuming and cannot be performed during use of the rechargeable battery.

One way to avoid performing the time-consuming measurements is to estimate the capacity and the internal resistance based on measurements performed during use of the rechargeable battery. The capacity and the internal resistance are estimated by comparing real-time measurements of battery parameters to a statistical model (e.g., a data model) associated with a specific type of the rechargeable battery being used. However, generating the statistical model incurs significant time and resource costs. For example, to generate the statistical model, testing is performed on a large number of rechargeable batteries. The batteries are monitored during repeated charging and discharging cycles and measurements are recorded. The measurements from the rechargeable batteries are correlated to create a statistical model representing an average rechargeable battery of the specific type. The testing process uses up the batteries involved. Thus, generating the statistical model requires significant resources to perform the testing as well as using up a large number of rechargeable batteries. If more than one type of rechargeable battery is used, additional statistical models are generated based test data of additional rechargeable batteries.

As well as requiring significant resources to generate statistical models, estimation based on statistical models results in estimated values that are based on performance of an average rechargeable battery. Performance of a particular rechargeable battery being used may vary from the performance of the average rechargeable battery, thus adding inaccuracies to the estimated values. Additionally, most statistical models are based on a full charge operation followed by a full discharge operation. The full charge operation and the full discharge operation may not accurately reflect use of a rechargeable battery in the field, thus adding additional inaccuracies to the estimated values.

### SUMMARY

Particular embodiments disclosed herein describe a model-independent battery forecaster configured to estimate battery parameters indicating battery life and performance. For example, the battery parameters may be estimated independently of a statistical model (e.g., a data model) associated with a rechargeable battery. The battery parameters may also be estimated independently of a type of the rechargeable battery being used. Thus, the battery forecaster eliminates time and resource intensive generation of type-specific statistical models.

To estimate the battery parameters indicating battery life and battery performance, other battery parameters of the rechargeable battery, such as current, voltage, and temperature, may be determined (e.g., measured) during an effective power cycle of the rechargeable battery. The effective power cycle may include multiple charge operations and multiple discharge operations. The charge operations and the discharge operations may occur in any order, and each charge operation or discharge operation may transfer less than a full capacity of the rechargeable battery. Thus, the effective power cycle is not limited to consecutive full charge operations and full discharge operations.

Upon completion of the effective power cycle, a remaining capacity, an internal resistance, and a reversible potential of the rechargeable battery may be estimated based on the current, the voltage, and the temperature. The remaining capacity may be associated with a remaining life of the rechargeable battery. Thus, knowledge of the remaining capacity and use conditions of the rechargeable battery enables estimation of the remaining life of the rechargeable battery. The internal resistance and the reversible potential may indicate power performance of the rechargeable battery, such as a maximum achievable power output of a next discharge operation. The remaining capacity, the internal resistance, and the reversible potential may be estimated based on the current, the voltage, and the temperature without a comparison to any statistical models. Additional data, such as changes in the remaining capacity, the internal resistance, and the reversible potential during the effective power cycle may be generated based on the estimated values. The additional data may indicate performance trends of the rechargeable battery.

In a particular embodiment, a method includes determining parameters of a rechargeable battery during an effective power cycle of the rechargeable battery. The parameters include a current provided by the rechargeable battery, a voltage across the rechargeable battery, and a temperature of the rechargeable battery. The effective power cycle includes multiple charge operations and multiple discharge operations. The method includes estimating a remaining capacity of the rechargeable battery based on the current, the voltage, and the temperature. The method also includes generating an output indicating the remaining capacity.

In another particular embodiment, a system includes a battery monitor configured to determine parameters of a rechargeable battery during an effective power cycle of the rechargeable battery. The parameters include a current provided by the rechargeable battery, a voltage across the rechargeable battery, and a temperature of the rechargeable battery. The effective power cycle includes multiple charge operations and multiple discharge operations. The system includes a battery forecaster configured to estimate a remaining capacity of the rechargeable battery based on the current, the voltage, and the temperature. The system also includes a memory coupled to the battery forecaster, the memory configured to store a data log including data indicating the remaining capacity.

In another particular embodiment, a computer-readable storage device stores instructions that, when executed by a processor, cause the processor to perform operations. The operations include determining parameters of a rechargeable battery during an effective power cycle of the rechargeable battery. The parameters include a current provided by the rechargeable battery, a voltage across the rechargeable battery, and a temperature of the rechargeable battery. The effective power cycle includes multiple charge operations and multiple discharge operations. The operations include estimating a remaining capacity of the rechargeable battery based on the current, the voltage, and the temperature. The operations also include generating an output indicating the remaining capacity.

The features, functions, and advantages that have been described can be achieved independently in various embodiments or may be combined in yet other embodiments, further details of which are disclosed with reference to the following description and drawings.

### BRIEF DESCRIPTION OF THE DRAWINGS

FIG. 1 is a block diagram that illustrates a particular embodiment of a system to estimate parameters indicating battery life and battery performance of a rechargeable battery;

FIGS. 2A-B are a flow chart of a particular embodiment of a method of estimating parameters indicating battery life and battery performance of a rechargeable battery during a lifetime of the rechargeable battery;

FIG. 3 is a flow chart of a particular embodiment of a method of estimating a remaining capacity of a rechargeable battery; and

FIG. 4 is a block diagram that illustrates a particular embodiment of a computing system to estimate parameters indicating battery life and battery performance of a rechargeable battery.

### DETAILED DESCRIPTION

Particular embodiments of the present disclosure are described below with reference to the drawings. In the description, common features are designated by common reference numbers throughout the drawings.

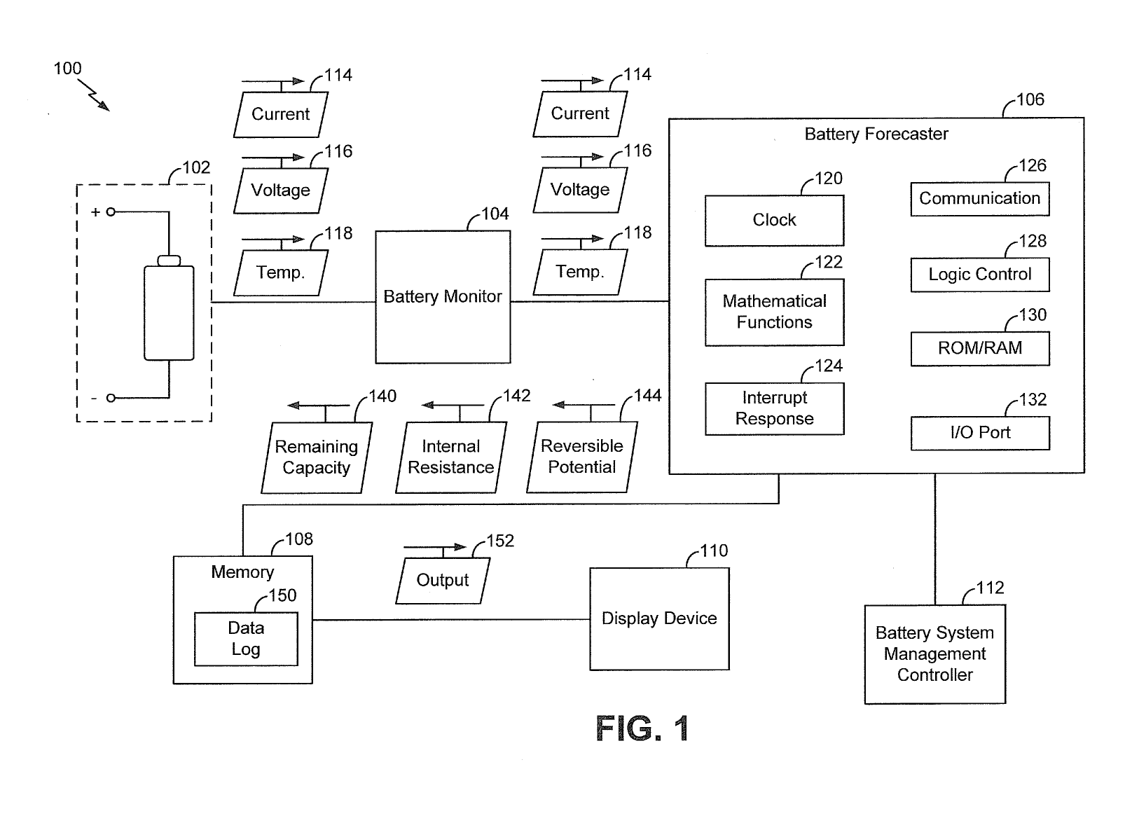

Referring to FIG. 1, a particular embodiment of a system to estimate parameters indicating battery life and battery performance of a rechargeable battery is depicted and generally designated 100. The system 100 includes a rechargeable battery 102, a battery monitor 104, a battery forecaster 106, a memory 108, a display device 110, and a battery system management controller 112. The system 100 enables estimation of one or more parameters that indicate remaining life and/or battery performance of the rechargeable battery 102. Although illustrated as individual components, in a particular embodiment, the system 100 may be included in a device that is powered by or coupled to the rechargeable battery 102.

The rechargeable battery 102 may be any type of rechargeable battery. For example, the rechargeable battery 102 may be a lithium battery or a lead-acid battery. The rechargeable battery 102 may be configured to power an aircraft, a spacecraft, a land craft, a computing device, a wireless device, or any other type of device. During use of the rechargeable battery 102 (e.g., while the rechargeable battery 102 powers a particular device), the rechargeable battery 102 may be monitored, as further described herein, so that the battery forecaster 106 may estimate one or more parameters of the rechargeable battery 102.

The battery monitor 104 may be configured to monitor the rechargeable battery 102 during use and to determine (e.g., measure values corresponding to) one or more parameters of the rechargeable battery 102. The battery monitor 104 may be coupled to the battery forecaster 106 and may be configured to provide the parameters to the battery forecaster 106. For example, the battery monitor 104 may include one or more sensors configured to measure the parameter values, such as a current 114 provided by the rechargeable battery 102, a voltage 116 across the rechargeable battery 102, and a temperature 118 of the rechargeable battery 102. The values of the parameters may be measured in real-time during use of the rechargeable battery 102. Although described as internal to the battery monitor 104, in an alternate embodiment, the sensors may be external to the battery monitor 104 and may provide measurements corresponding to the parameters to the battery monitor 104. The battery monitor 104 may be further configured to perform signal processing on the current 114, the voltage 116, and the temperature 118. For example, the current 114, the voltage 116, and the temperature 118 may be measured as analog signals, and the battery monitor 104 may be configured to perform analog-to-digital (A/D) conversion to convert the analog signals to digital signals. The battery monitor 104 may also perform anti-alias filtering on the signals.

The battery forecaster 106 may be configured to estimate one or more parameters indicating battery life or battery performance based on the current 114, the voltage 116, and the temperature 118, as further described herein. The battery forecaster 106 may include one or more processing modules, such as a clock module 120, a mathematical function module 122, an interrupt response module 124, a communication module 126, a logic control module 128, a ROM/RAM 130, and an input/output (I/O) port 132. The processing modules 120-132 may be configured to perform one or more operations or to store one or more values to enable the battery forecaster 106 to estimate the parameters based on the current 114, the voltage 116, and the temperature 118. The example illustrated in FIG. 1 is not limiting. For example, in other embodiments, the battery forecaster 106 may include only a subset (e.g., not all) of the processing modules 120-132.

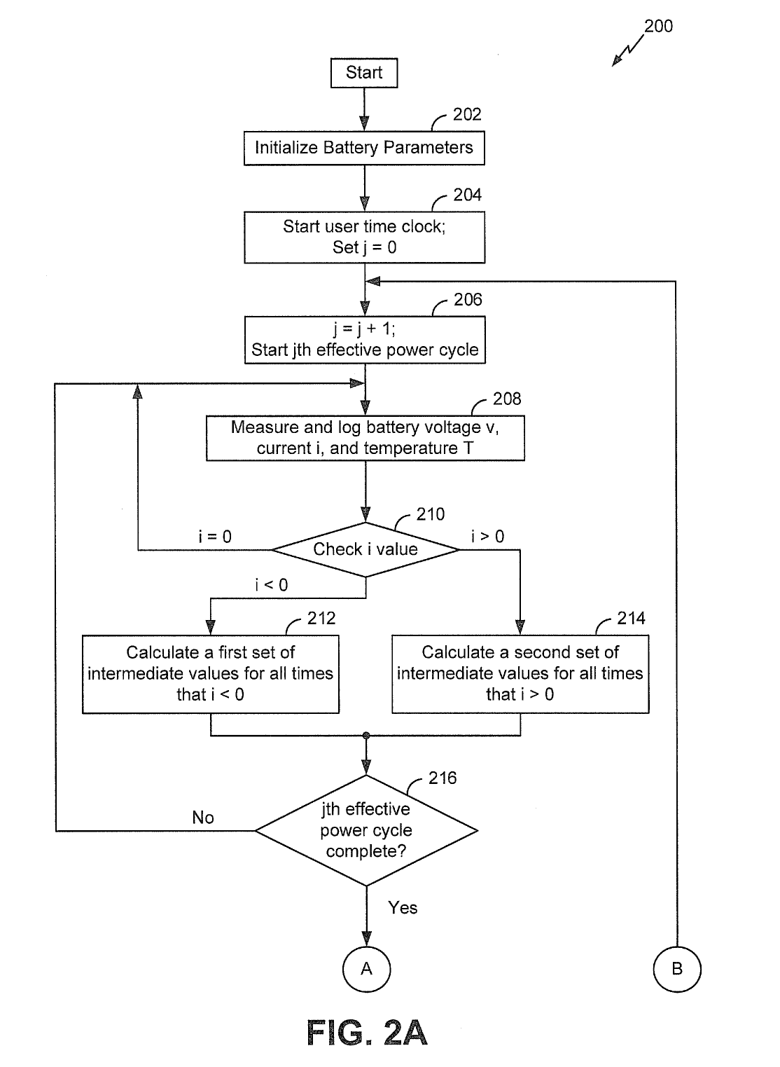

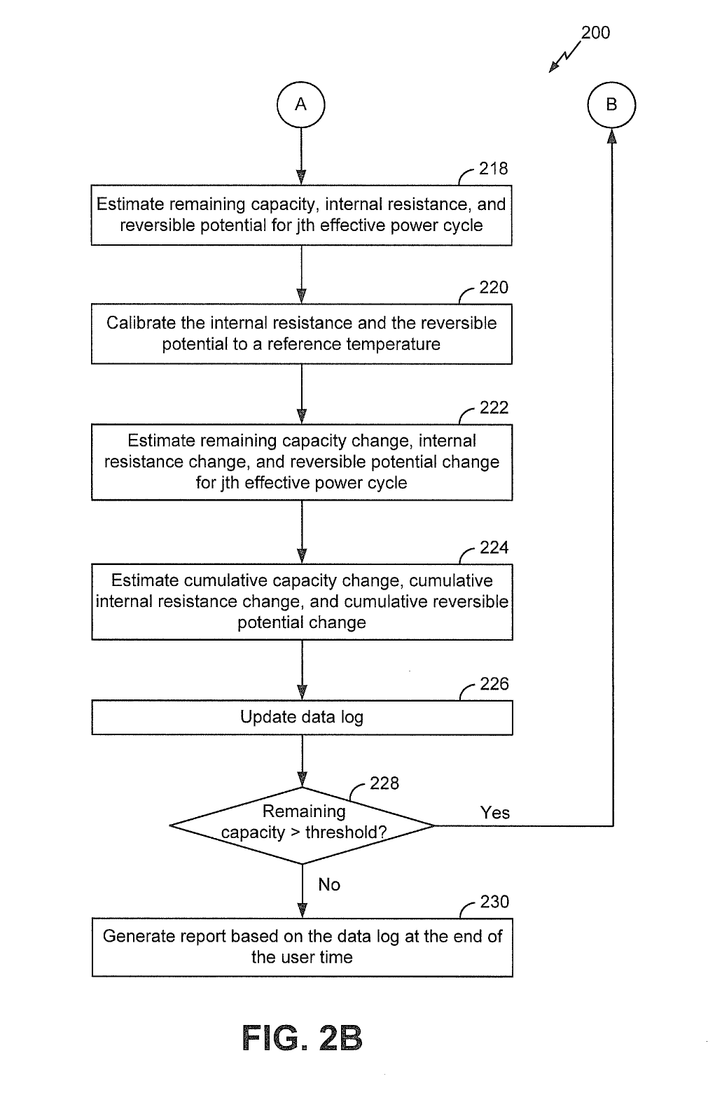

The parameters estimated by the battery forecaster 106 may include a remaining capacity 140, an internal resistance 142, and a reversible potential 144. The battery forecaster 106 may also be configured to estimate changes in the remaining capacity 140, the internal resistance 142, and the reversible potential 144 as compared to a previous effective power cycle or as compared to initial values, as further described with reference to FIGS. 2A-B. The battery forecaster 106 may be configured to provide data indicating the estimated parameters to the memory 108 upon completion of each effective power cycle. Operation of the battery forecaster 106 may be controlled by the battery system management controller 112.

The memory 108 may include a data log 150. The data log 150 may be configured to store data indicating estimated parameters for each of one or more effective power cycles. For example, the data log 150 may store data indicating the remaining capacity 140, the internal resistance 142, and the reversible potential 144 for each of multiple effective power cycles. The memory 108 may also be configured to generate an output 152 based on the data log 150 and to provide the output 152 to the display device 110. The display device 110 may be configured to display the output 152. For example, the display device 110 may be configured to display battery life and battery performance information of the rechargeable battery 102. The battery life and battery performance information may be a report based on the data log 150.

During operation, the battery monitor 104 may monitor the rechargeable battery 102 and may measure parameters of the rechargeable battery 102, including the current 114, the voltage 116, and the temperature 118, during an effective power cycle of the rechargeable battery. The battery forecaster 106 may receive values of the current 114, the voltage 116, and the temperature 118 from the battery monitor 104. The battery forecaster 106 may determine an end of the effective power cycle and, in response to the determination, may estimate the remaining capacity 140, the internal resistance 142, and the reversible potential 144 based on the current 114, the voltage 116, and the temperature 118. The effective power cycle may include multiple charge operations and multiple discharge operations of the rechargeable battery 102. Determination of the end of the effective power cycle and estimation of the remaining capacity 140, the internal resistance 142, and the reversible potential 144 are described in further detail with reference to FIGS. 2A-B. Data indicating the estimated parameters 140-144 as well as any additional estimated parameters may be provided to the memory 108 and may be stored in the data log 150. The output 152 based on the data log 150 may be generated and provided to the display device 110 for display to a user. Additionally or alternatively, the output 152 may be based on the data indicating the estimated parameters 140-144 (e.g., without storage in the memory 108).

The battery forecaster 106 enables estimation of parameters indicating battery life and battery performance of the rechargeable battery 102 without using a lookup table to compare measured values to a statistical model. Thus, the battery forecaster 106 enables estimation of the parameters independently of a statistical model (e.g., a data model). The battery forecaster 106 uses less memory than a forecaster that stores data from a statistical model in a lookup table. The battery forecaster 106 also reduces costs by eliminating the testing and generation of the statistical model. Additionally, the battery forecaster 106 may estimate parameters of any type of rechargeable battery. Additionally, because the battery forecaster 106 uses real-time measurements of the rechargeable battery 102, inaccuracies based on performance-variance are reduced.

Referring to FIGS. 2A-B, a flow chart of a particular embodiment of a method 200 of estimating parameters indicating battery life and battery performance of a rechargeable battery during a lifetime of the rechargeable battery is depicted. The method 200 may be performed by a battery forecaster, such as the battery forecaster 106 of FIG. 1, for a rechargeable battery, such as the rechargeable battery 102 of FIG. 1.

The method 200 begins and battery parameters are initialized, at 202. The battery parameters may be initialized based on a user input. For example, a user input indicating initial values may be received at the battery forecaster. The initial values may be determined based on simple offline tests and measurements of the rechargeable battery 102. The initial values may include an initial reversible potential E_{0,ref}, an initial internal resistance R_{0,ref}, an initial capacity C₀, an initial state of charge soc₀, a reference temperature T_{ref}, a battery temperature coefficient α, a battery data sampling time step Δt, an input error parameter ε, or a combination thereof. In a particular embodiment, the reference temperature T_{ref} may be pre-set to a value associated with room temperature (298 K). The battery parameters may be initialized based on the initial values. After initialization, the battery parameters (e.g., the initial values) may be used in estimating other battery parameters, as further described herein.

A user time clock may be started, at 204. For example, the battery forecaster may start a clock corresponding to user time. The clock may track a duration of use of the battery by a particular user (e.g., user time). Additionally, a variable j configured to track a current effective power cycle may be initialized to zero.

A value of j may be incremented by one, at 206. The battery forecaster may increment the value of j to indicate a beginning of a current effective power cycle (e.g., a jth effective power cycle). An effective power cycle may include multiple charge operations and multiple discharge operations of the rechargeable battery (e.g., the effective power cycle is not limited to a full charge operation followed consecutively by a full discharge operation). The multiple charge operations and the multiple discharge operations may occur in any order and each may transfer less than or equal to the capacity of the battery. The current (e.g., jth) effective power cycle may continue until a first amount of electric charge associated with the multiple charge operations and a second amount of electric charge associated with the multiple discharge operations each approximate a remaining capacity associated with a previous effective power cycle, as further described herein. The first amount of electric charge applied to the rechargeable battery during the multiple charge operations and the second amount of electric charge discharged from the rechargeable battery during the multiple discharge operations each may approximate a previous remaining capacity Cⱼ₋₁ of a previous effective power cycle. A degree of approximation between the first amount of electric charge (or the second amount of electric charge) and the previous remaining capacity Cⱼ₋₁ may be based on the input error parameter ε. A time period (e.g., a duration) Δtⱼ of the jth effective power cycle may satisfy Equation 1, where E is a reversible potential of the rechargeable battery, i is a current provided by the rechargeable battery, and Ēⱼ is a reversible potential of the rechargeable battery associated with the jth effective power cycle:

$${\int }_{Δ {t}_{j}} E \cdot \vert i \vert \cdot d t = 2 \cdot {C}_{j - 1} \cdot {\overline{E}}_{j} \qquad Equation ( 1 )$$

Parameters of the rechargeable battery may be measured during the jth effective power cycle, at 208. For example, the battery forecaster may measure values of the parameters directly from the rechargeable battery or may receive measurements from another system component, such as the battery monitor 104 of FIG. 1. The parameters may include a current i provided by the rechargeable battery, a voltage v across the rechargeable battery, and a temperature T of the rechargeable battery. The parameters may be measured at time increments based on the battery data sampling time step Δt.

A value of the current i may be checked, at 210. The value the current i may be checked to determine how to process the current i, the voltage v, and the temperature T. For example, if no current is detected (e.g., i=0), then the battery forecaster may continue to measure the parameters. If a negative current is detected (e.g., i<0), then the rechargeable battery is being charged. The battery forecaster may calculate a first set of intermediate values when the current i is negative, at 212. The first set of values may be associated with the multiple charge operations. For example, the first set of intermediate values may include a time period (e.g., a duration) Δt_{c,j} of the multiple charge operations and one or more calculations based on the current i, the voltage v, and the temperature T during the time period Δ_{c,j}. As a particular example, the first amount of electric charge applied to the rechargeable battery during the multiple charge operations may be determined by performing an integral of the absolute value of the current i for the time period Δ_{c,j}. If a positive current is detected (e.g., i>0), then the rechargeable battery is being discharged. The battery forecaster may calculate a second set of intermediate values when the current i is positive, at 214. For example, the second set of intermediate values may include a time period (e.g., a duration) Δ_{d,j} of the multiple discharge operations and one or more calculations based on the current i, the voltage v, and the temperature T during the time period Δ_{d,j}. As a particular example, the second amount of electric charge discharged from the rechargeable battery during the multiple discharge operations may be determined by performing an integral of the current i for the time period Δ_{d,j}. One or more parameters of the rechargeable battery may be estimated based on the first set of intermediate values and the second set of intermediate values, as further described herein.

The battery forecaster may determine whether the jth effective power cycle is complete, at 216. The determination may be based on a relationship of the first amount of electric charge (e.g., the amount of electric charge applied to the rechargeable battery during the multiple charge operations) and the second amount of electric charge (e.g., the amount of electric charge discharged from the rechargeable battery during the multiple discharge operations) to a threshold. The threshold may be the input error parameter s that indicates how closely the first amount of electric charge and the second amount of electric charge approximate a remaining capacity of a previous (e.g., a j−1) effective power cycle. The jth effective power cycle may be complete when the Inequality 1 and Inequality 2 each evaluate to true:

$$\begin{matrix}\vert {\overline{C}}_{j - 1} - {\int }_{Δ {t}_{c , j}} \vert i \vert d t \vert < ɛ & Inequality ( 1 ) \\ \vert {\overline{C}}_{j - 1} - {\int }_{Δ {t}_{d , j}} i d t \vert < ɛ & Inequality ( 2 )\end{matrix}$$

Determining whether the jth effective power cycle is complete may include comparing an absolute value of a first difference between the remaining capacity of the previous effective power cycle and the first amount of electric charge to the input error parameter ε (e.g., the threshold). Determining whether the jth effective power cycle is complete may also include comparing an absolute value of a second difference between the remaining capacity of the previous effective power cycle and the second amount of electric charge to the input error parameter ε. A determination that the jth effective power cycle is complete may be based on the absolute values of the first difference and the second difference being less than the input error parameter ε. In response to the determination that the jth effective power is complete, the method 200 continues to 218. If the absolute value of the first difference or the absolute value of the second difference is not less than the input error parameter ε, the jth effective power cycle continues and the method 200 returns to 208, where the battery forecaster continues to monitor the current i, the voltage v, and the temperature T.

Responsive to a determination that the jth effective power cycle is complete, a remaining capacity C̅ⱼ, an internal resistance R̅ⱼ, and a reversible potential Ēⱼ may be estimated for the jth effective power cycle, at 218. The remaining capacity C̅ⱼ, the internal resistance R̅ⱼ, and the reversible potential Ēⱼ may be time-averaged values for the jth effective power cycle. The remaining capacity C̅ⱼ may be estimated using Equation 2, where C_{c,j} is the first amount of electric charge applied during the multiple charge operations of the jth effective power cycle and C_{d,j} is the second amount of electric charge discharged during the multiple discharge operations of the jth effective power cycle:

C̅ⱼ=½(C_{c,j}+C_{d,j}) Equation (2)

Based on Equation 2, the time period Δtⱼ of the jth effective power cycle may be a sum of the time period Δt_{c,j} and the time period Δt_{d,j}. The first amount of electric charge may be calculated by performing an integral of the current i measured during the multiple charge operations using Equation 3:

$${C}_{c , j} = {\int }_{Δ {t}_{c , j}} \vert i \vert d t \qquad Equation ( 3 )$$

The second amount of electric charge may be calculated by performing an integral of the current i measured during the multiple discharge operations using Equation 4:

$${C}_{d , j} = {\int }_{Δ {t}_{d , j}} i d t \qquad Equation ( 4 )$$

The internal resistance R̅ⱼ may be estimated using Equation 5:

$${\overline{R}}_{j} = \frac{{\int }_{Δ {t}_{j , c}} v \cdot \vert i \vert \cdot d t - {\int }_{Δ {t}_{j , d}} v \cdot i \cdot d t}{{\int }_{Δ {t}_{j}} {i}^{2} \cdot d t} \qquad Equation ( 5 )$$

The reversible potential Ēⱼ may be estimated using Equation 6:

$${\overline{E}}_{j} = \frac{{\int }_{Δ {t}_{j , c}} v \cdot \vert i \vert \cdot d t + {\int }_{Δ {t}_{j , d}} v \cdot i \cdot d t + {\overline{R}}_{j} ( {\int }_{Δ {t}_{j , d}} {i}^{2} \cdot d t - {\int }_{Δ {t}_{j , c}} {i}^{2} \cdot d t )}{{\int }_{Δ {t}_{j}} \vert i \vert \cdot d t} \qquad Equation ( 6 )$$

As may be appreciated from Equations 2-6, the remaining capacity C̅ⱼ, the internal resistance R̅ⱼ and the reversible potential Ēⱼ may be estimated without reliance on a statistical model of the rechargeable battery. Additionally, Equations 2-6 do not depend on variables associated with a specific type of rechargeable battery. For example, Equations 2-6 are not based on variables indicating a material or chemical used to manufacture the rechargeable battery, a power level of the rechargeable battery, a configuration of the rechargeable battery, or any other type-specific factor. Thus, the remaining capacity C̅ⱼ, the internal resistance R̅ⱼ and the reversible potential Ēⱼ may be estimated independently of a type of rechargeable battery and independently of a statistical model associated with the rechargeable battery.

The internal resistance R̅ⱼ and the reversible potential Ēⱼ may be calibrated to the reference temperature T_{ref}, at 220. In order to calibrate the internal resistance R̅ⱼ and the reversible potential Ēⱼ, a time-averaged temperature T̅ⱼ of the rechargeable battery for the jth effective power cycle may be determined using Equation 7:

$${\overline{T}}_{j} = \frac{{\int }_{Δ {t}_{j}} T \cdot d t}{Δ {t}_{j}} \qquad Equation ( 7 )$$

The internal resistance R̅ⱼ may be calibrated to the reference temperature based on the temperature T̅ⱼ, the reference temperature T_{ref}, and the temperature coefficient α of the rechargeable battery. For example, a temperature-calibrated (e.g., temperature-corrected) internal resistance R̅_{j,ref} may be estimated using Equation 8:

$${\overline{R}}_{j , ref} = \frac{{\overline{R}}_{j}}{1 + α ( {\overline{T}}_{j} - {T}_{ref} )} \qquad Equation ( 8 )$$

The reversible potential Ēⱼ may be calibrated to the reference temperature based on the temperature T̅ⱼ, the reference temperature T_{ref}, and the temperature coefficient α of the rechargeable battery. For example, a temperature-calibrated (e.g., temperature-corrected) reversible potential Ē_{j,ref} may be estimated using Equation 9:

$${\overline{E}}_{j , ref} = \frac{{T}_{ref}}{{\overline{T}}_{j}} \cdot {\overline{E}}_{j} \qquad Equation ( 9 )$$

Parameters indicating performance trends of the rechargeable battery, such as changes in the remaining capacity C̅ⱼ, the internal resistance R̅ⱼ, and the reversible potential Ēⱼ may be estimated for the jth effective power cycle, at 222. For example, a change in remaining capacity (e.g., a capacity fade) ΔCⱼ, a change in internal resistance (e.g., a resistance increase) ΔR_{j,ref} and a change in reversible potential (e.g., a reversible potential loss) ΔE_{j,ref} may be estimated. The changes may be estimated by comparing values corresponding to the jth effective power cycle to values corresponding to a previous effective power cycle (e.g., the j−1 effective power cycle). For example, the change in remaining capacity ΔCⱼ may be generated based on the remaining capacity C̅ⱼ and a previous remaining capacity C̅ⱼ₋₁. If the jth effective power cycle is a first effective power cycle, initial values received during initialization may be used for the values corresponding to the previous effective power cycle.

The change in remaining capacity ΔCⱼ may be estimated using Equation 10:

ΔCⱼ= C̅ⱼ₋₁− C̅ⱼ Equation (10)

The change in internal resistance ΔR_{j,ref} may be estimated using Equation 11:

ΔR_{j,ref}= R̅_{j,ref}− R̅_{j-1,ref} Equation (11)

The change in reversible potential ΔE_{j,ref} may be estimated using Equation 12:

ΔE_{j,ref}=Ē_{j-1,ref}−Ē_{j,ref} (12)

Cumulative changes in the remaining capacity C̅ⱼ, the internal resistance R̅ⱼ, and the reversible potential Ēⱼ may be estimated for the jth effective power cycle, at 224. For example, a cumulative change in remaining capacity (e.g., a cumulative capacity fade) ΔCⱼ^{total}, a cumulative change in internal resistance (e.g., a cumulative resistance increase) ΔR_{j,ref}^{total}, and a cumulative change in reversible potential (e.g., a cumulative reversible potential loss) ΔE_{j,ref}^{total} may be estimated. The changes may be estimated by comparing values corresponding to the jth effective power cycle to the initial values received during initialization. For example, the cumulative change in remaining capacity ΔCⱼ^{total} may be generated based on the remaining capacity C̅ⱼ and the initial capacity C₀.

The cumulative change in remaining capacity ΔCⱼ^{total} may be estimated using Equation 13, where C₀ is the initial capacity of the rechargeable battery received during initialization:

$$Δ {C}_{j}^{total} = {\sum }_{k = 1}^{k = j} Δ {C}_{k} = {C}_{0} - {\overline{C}}_{j} \qquad Equation ( 13 )$$

The cumulative change in internal resistance ΔR_{j,ref}^{total} may be estimated using Equation 14, where R_{0,ref} is the initial internal resistance of the rechargeable battery received during initialization:

$$Δ {R}_{j , ref}^{total} = {\sum }_{k = 1}^{k = j} Δ {R}_{k , ref} = {\overline{R}}_{j , ref} - {R}_{0 , ref} \qquad Equation ( 14 )$$

The cumulative change in reversible potential ΔE_{j,ref}^{total} may be estimated using Equation 15, where E_{0,ref} is the initial reversible potential of the rechargeable battery received during initialization:

$$Δ {E}_{j , ref}^{total} = {\sum }_{k = 1}^{k = j} Δ {E}_{k , ref} = {E}_{0 , ref} - {\overline{E}}_{j , ref} \qquad Equation ( 15 )$$

A data log may be updated, at 226. For example, the data log may be stored in a memory, such as the data log 150 in the memory 108 of FIG. 1. The data log may store data indicating the estimated battery parameters of the rechargeable battery. For example, data indicating the remaining capacity C̅ⱼ, the internal resistance R̅ⱼ, the reversible potential Ēⱼ, the change in remaining capacity ΔCⱼ, the change in internal resistance ΔR_{j,ref}, the change in reversible potential ΔE_{j,ref}, the cumulative change in remaining capacity ΔCⱼ^{total}, the cumulative change in internal resistance ΔR_{j,ref}^{total}, the cumulative change in reversible potential ΔE_{j,ref}^{total}, or a combination thereof, may be provided to the memory for storage in the data log after the jth effective power cycle is complete. The data log may include data indicating C_{new}, R_{new}, E_{new}, ΔC_{new}^{total}, ΔR_{new}^{total}, and ΔE_{new}^{total}, which correspond to parameters of the rechargeable battery after the jth effective power cycle. The data log may be updated by setting C_{new}= C̅ⱼ, setting R_{new}= R̅j, setting E_{new}=Ēⱼ, setting ΔC_{new}^{total}=ΔCⱼ^{total}, setting ΔR_{new}^{total}=ΔR_{j,ref}^{total}, and setting ΔE_{new}^{total}=ΔE_{j,ref}^{total}.

Updating the data log may include generating an output based on the data log. For example, the output may be generated based on C_{new}, R_{new}, E_{new}, ΔC_{new}^{total}, ΔR_{new}^{total}, ΔE_{new}^{total}, or other parameter values indicated by data stored in the data log. The output may be generated for display on a display device, such as the display device 110 of FIG. 1. Generating the output may enable the user to monitor performance characteristics and trends of the rechargeable battery after each effective power cycle.

The data log may include an indication of a remaining life of the rechargeable battery. For example, the battery forecaster may estimate the remaining life of the rechargeable battery based on the remaining capacity C̅ⱼ and input data indicating conditions of use of the rechargeable battery. For example, the conditions of use may include power output requirements, rates and/or durations of charge operations or discharge operations, temperature of use, or other data indicating how the rechargeable battery is being used. The input data may be received during the initialization of the battery parameters. The remaining life of the rechargeable battery may be estimated as a number of hours the rechargeable battery may be used at the particular conditions until an end of life of the rechargeable battery. Estimating the remaining life as the number of hours may provide a more user-friendly indication of remaining battery life than the remaining capacity C̅ⱼ.

The remaining capacity C̅ⱼ may be compared to a threshold, at 228. The threshold may be a capacity threshold (C_{threshold}) that indicates a minimum capacity that the rechargeable battery can reach without causing problems during use. For example, the capacity threshold may be based on use conditions of the rechargeable battery, such as power requirements of a device being powered by the rechargeable battery. The capacity threshold may be received via user input during the initialization. If the remaining capacity C̅ⱼ exceeds (e.g., is greater than) the capacity threshold, sufficient capacity remains in the rechargeable battery and the method 200 continues to 206. Returning to 206 causes the battery forecaster to estimate a second remaining capacity associated with a second effective power cycle (e.g., a j+1 effective power cycle) in response to determining that the remaining capacity C̅ⱼ exceeds the capacity threshold. For example, the battery forecaster may estimate a remaining capacity C̅ⱼ₊₁, an internal resistance R̅ⱼ₊₁, and a reversible potential Ēⱼ₊₁ based on the current i, the voltage v, and the temperature T measured during the second effective power cycle.

If the remaining capacity C̅ⱼ does not exceed (e.g., is less than or equal to) the capacity threshold C_{threshold}, the rechargeable battery no longer contains sufficient capacity for additional use (e.g., one or more problems may occur during additional use of the rechargeable battery). The battery forecaster may generate an indication of an end of life of the rechargeable battery for display via the display device. For example, a report may be generated based on the data log at the end of the user time, at 230. The end of the user time is indicated by the remaining capacity C̅ⱼ being less than or equal to the capacity threshold C_{threshold}. The report may be output via the display device. The report may include information indicating values of C_{new}, R_{new}, E_{new}, ΔC_{new}^{total}, ΔR_{new}^{total}, and ΔE_{new}^{total} estimated after a last effective power cycle, as well as a total number of effective power cycles and a total user time (e.g., a total duration of use of the rechargeable battery). The user may use the information in the report during selection of a replacement rechargeable battery, or for other purposes.

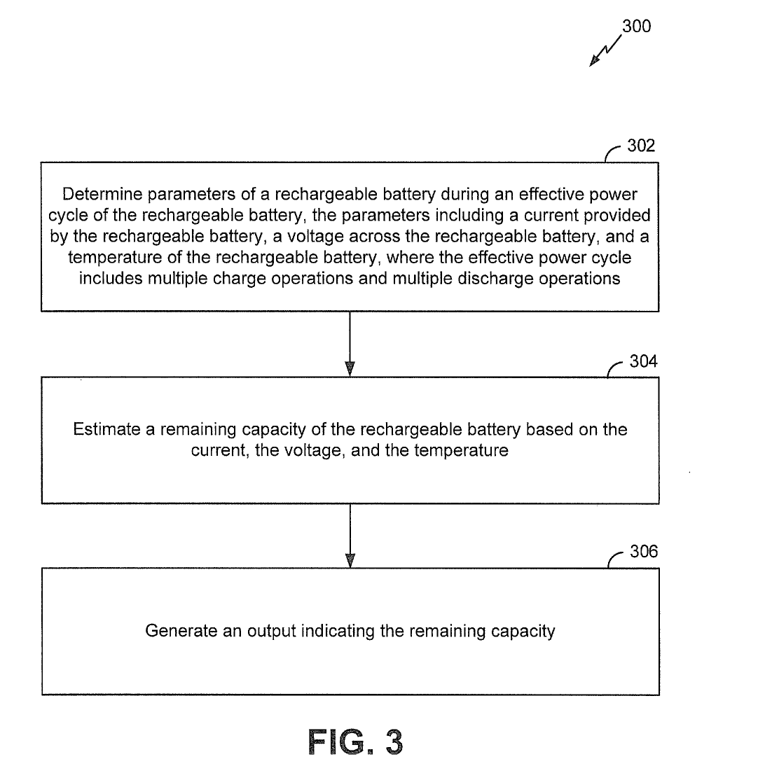

Referring to FIG. 3, a flow chart of a particular embodiment of a method 300 of estimating a remaining capacity of a rechargeable battery is depicted. The method 300 may be performed by a battery forecaster to estimate battery life or battery performance of the rechargeable battery. For example, the method 300 may be performed by the battery forecaster 106 on the rechargeable battery 102 of FIG. 1.

Parameters of the rechargeable battery are measured during an effective power cycle of the rechargeable battery, at 302. The parameters may include a current provided by the rechargeable battery, a voltage across the rechargeable battery, and a temperature of the rechargeable battery, such as the current 114, the voltage 116, and the temperature 118 of FIG. 1, respectively. The effective power cycle may include multiple charge operations and multiple discharge operations.

The remaining capacity of the rechargeable battery is estimated based on the current, the voltage, and the temperature, at 304. For example, the remaining capacity may be the remaining capacity 140 of FIG. 1 and may be estimated using Equations 2-4. An output indicating the remaining capacity may be generated, at 306. For example, the output may be the output 152 of FIG. 1. The output may be based on a data log storing data that indicates the remaining capacity, and the output may be displayed via a display device.

An internal resistance of the battery may be estimated based on the current, the voltage, and the temperature. For example, the internal resistance may be the internal resistance 142 of FIG. 1 and may be estimated using Equation 5. A reversible potential of the battery may also be estimated based on the current, the voltage, and the temperature. For example, the reversible potential may be the reversible potential 144 of FIG. 1 and may be estimated using Equation 6. The output may also indicate the internal resistance and the reversible potential. Additional values may be estimated based on the current, the voltage, and the temperature, as further explained with reference to FIGS. 1 and 2A-B.

The method 200 of FIGS. 2A-B and the method 300 of FIG. 3 may be initiated or controlled by a field-programmable gate array (FPGA) device, an application-specific integrated circuit (ASIC), a processing unit, such as a central processing unit (CPU), a digital signal processor (DSP), a controller, another hardware device, a firmware device, or any combination thereof. As an example, method 200 of FIGS. 2A-B and the method 300 of FIG. 3 may be initiated or controlled by one or more processors.

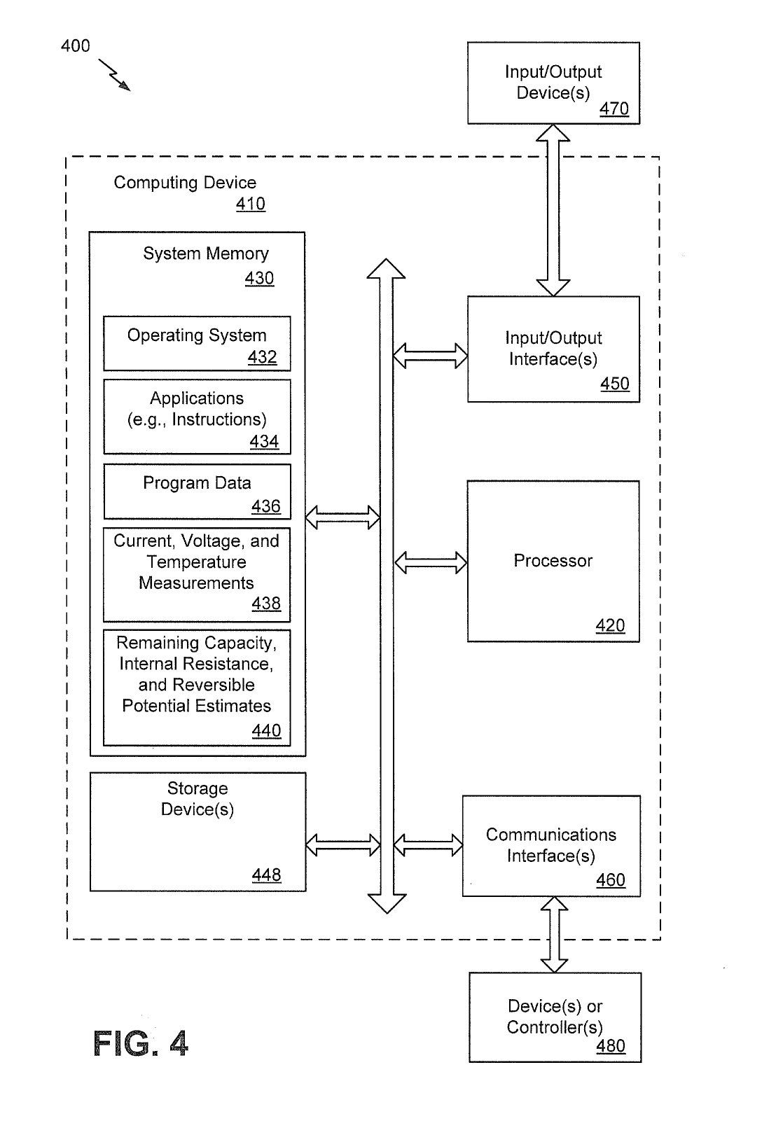

FIG. 4 is a block diagram of a computing environment 400 including a computing device 410 operable to estimate parameters indicating battery life and battery performance of a rechargeable battery. For example, the computing device 410 may be included within or correspond to the battery forecaster 106 of FIG. 1.

The computing device 410 may include at least one processor 420. Within the computing device 410, the at least one processor 420 may communicate with a system memory 430, one or more storage devices 448, one or more input/output interfaces 450, one or more communications interfaces 460, or a combination thereof.

The system memory 430 may include volatile memory devices (e.g., random access memory (RAM) devices), nonvolatile memory devices (e.g., read-only memory (ROM) devices, programmable read-only memory, and flash memory), or both. The system memory 430 may include an operating system 432, which may include a basic input/output system for booting the computing device 410 as well as a full operating system to enable the computing device 410 to interact with users, other programs, and other devices. The system memory 430 may also include one or more applications (e.g., instructions) 434, program data 436, data corresponding to current, voltage, and temperature measurements 438, and remaining capacity, internal resistance, and reversible potential estimates 440. The program data 436 may include data used by the applications 434 to perform respective functions of the applications 434. The applications 434 may include instructions executable by the at least one processor 420 to estimate one or more parameters associated with battery life and battery performance of a rechargeable battery. The current, voltage, and temperature measurements 438 may include values used during to generate the remaining capacity, internal resistance, and reversible potential estimates 440.

The one or more storage devices 448 may include nonvolatile storage devices, such as magnetic disks, optical disks, or flash memory devices. The storage devices 448 may include both removable and non-removable memory devices. In a particular embodiment, the storage devices 448 may be configured to store the operating system 432, the applications 434, the program data 436, the current, voltage, and temperature measurements 438, the remaining capacity, internal resistance, and reversible potential estimates 440, or a combination thereof. The system memory 430 and the storage devices 448 are physical devices and are not a signal.

In a particular embodiment, the at least one processor 420 is configured to execute computer executable instructions, such as the applications 434, stored at the system memory 430. The instructions may be executable to cause the at least one processor 420 to perform operations. The operations may include measuring parameters of a rechargeable battery during an effective power cycle of the rechargeable battery. The parameters may include a current provided by the rechargeable battery, a voltage across the rechargeable battery, and a temperature of the rechargeable battery. The effective power cycle may include multiple charge operations and multiple discharge operations. The operations may include estimating a remaining capacity of the rechargeable battery based on the current, the voltage, and the temperature (e.g., the current, voltage, and temperature measurements 438). The remaining capacity, internal resistance, and reversible potential estimates 440 may include the remaining capacity. The operations may further include generating an output indicating the remaining capacity.

The one or more input/output interfaces 450 may enable the computing device 410 to communicate with one or more input/output devices 470 to facilitate user interaction. For example, the one or more input/output interfaces 450 may be adapted to receive input from a user, to receive input from another computing device, or a combination thereof. The input/output interfaces 450 may conform to one or more standard interface protocols, including serial interfaces (e.g., universal serial bus (USB) interfaces or Institute of Electrical and Electronics Engineers (IEEE) interface standards), parallel interfaces, display adapters, audio adapters, or custom interfaces. The input/output devices 470 may include user interface devices and displays, including some combination of buttons, keyboards, pointing devices, displays, speakers, microphones, touch screens, and other devices. The processor 420 may detect interaction events based on user input received via the input/output interfaces 450. Additionally, the processor 420 may send a display to a display device via the input/output interfaces 450.

The one or more communications interfaces 460 may enable the computing device 410 to communicate with one or more other computing devices or controllers 480. The one or more communications interfaces 460 may include wired Ethernet interfaces, Institute of Electrical and Electronics Engineers (IEEE) 802 wireless interfaces, Bluetooth communication interfaces, electrical (or power line) interfaces, optical or radio frequency interfaces, or other wired or wireless interfaces. The other computer devices or controllers 480 may include host computers, servers, workstations, portable computers, telephones, tablet computers, or any other communication device or component.

Examples described above illustrate but do not limit the disclosure. It should also be understood that numerous modifications and variations are possible in accordance with the principles of the present disclosure. Accordingly, the scope of the disclosure is defined by the following claims and their equivalents.

The illustrations of the examples described herein are intended to provide a general understanding of the structure of the various embodiments. The illustrations are not intended to serve as a complete description of all of the elements and features of apparatus and systems that utilize the structures or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. For example, method steps may be performed in a different order than shown in the figures or one or more method steps may be omitted. Accordingly, the disclosure and the figures are to be regarded as illustrative rather than restrictive.

Moreover, although specific examples have been illustrated and described herein, it should be appreciated that any subsequent arrangement designed to achieve the same or similar results may be substituted for the specific embodiments shown. This disclosure is intended to cover any and all subsequent adaptations or variations of various embodiments. Combinations of the above embodiments, and other embodiments not specifically described herein, will be apparent to those of skill in the art upon reviewing the description.

The Abstract of the Disclosure is submitted with the understanding that it will not be used to interpret or limit the scope or meaning of the claims. In addition, in the foregoing Detailed Description, various features may be grouped together or described in a single embodiment for the purpose of streamlining the disclosure. As the following claims reflect, the claimed subject matter may be directed to less than all of the features of any of the disclosed examples.

1. A method comprising:
determining, by a battery forecaster comprising at least one processor, parameters of a rechargeable battery during an effective power cycle of the rechargeable battery, the parameters including a current provided by the rechargeable battery, a voltage across the rechargeable battery, and a temperature of the rechargeable battery, wherein the effective power cycle includes multiple charge operations and multiple discharge operations;
estimating, by the battery forecaster, a remaining capacity of the rechargeable battery based on the current, the voltage, and the temperature; and
generating, by the battery forecaster, an output indicating the remaining capacity.

2. The method of claim 1, further comprising:
estimating an internal resistance of the rechargeable battery based on the current, the voltage, and the temperature; and
estimating a reversible potential of the rechargeable battery based on the current, the voltage, and the temperature, wherein the output further indicates the internal resistance and the reversible potential.

3. The method of claim 2, further comprising calibrating the internal resistance and the reversible potential to a reference temperature based on the temperature, the reference temperature, and a temperature coefficient of the rechargeable battery.

4. The method of claim 1, wherein the remaining capacity is estimated independently of a type of the rechargeable battery.

5. The method of claim 1, wherein the remaining capacity is estimated independently of a statistical model associated with the rechargeable battery.

6. The method of claim 1, further comprising comparing the remaining capacity to a threshold, wherein the output indicates an end of life of the rechargeable battery when the remaining capacity is less than or equal to the threshold.

7. The method of claim 1, further comprising estimating a remaining life of the rechargeable battery based on the remaining capacity and input data indicating conditions of use of the rechargeable battery.

8. The method of claim 1, wherein estimating the remaining capacity comprises generating a first set of values associated with the multiple charge operations and generating a second set of values associated with the multiple discharge operations, wherein the first set of values and the second set of values are generated based on the current, the voltage, and the temperature, and wherein the remaining capacity is based on the first set of values and the second set of values.

9. The method of claim 1, further comprising determining whether the effective power cycle is complete, wherein the remaining capacity is estimated in response to a determination that the effective power cycle is complete.

10. The method of claim 9, wherein determining whether the effective power cycle is complete is based on a relationship of a first amount of electric charge and a second amount of electric charge to a threshold, wherein the first amount of electric charge is associated with the multiple charge operations, and wherein the second amount of electric charge is associated with the multiple discharge operations.

11. The method of claim 10, wherein determining whether the effective power cycle is complete comprises:
comparing a first difference between a previous remaining capacity and the first amount of electric charge to the threshold, wherein the previous remaining capacity is associated with a previous effective power cycle; and
comparing a second difference between the previous remaining capacity and the second amount of electric charge to the threshold, wherein the determination that the effective power cycle is complete is based on the first difference being less than the threshold and the second difference being less than the threshold.

12. The method of claim 10, wherein the threshold is an input error parameter associated with the rechargeable battery.

13. A system comprising:
a battery monitor configured to determine parameters of a rechargeable battery during an effective power cycle of the rechargeable battery, the parameters including a current provided by the rechargeable battery, a voltage across the rechargeable battery, and a temperature of the rechargeable battery, wherein the effective power cycle includes multiple charge operations and multiple discharge operations;
a battery forecaster configured to estimate a remaining capacity of the rechargeable battery based on the current, the voltage, and the temperature; and
a memory coupled to the battery forecaster, the memory configured to store a data log including data indicating the remaining capacity.

14. The system of claim 13, wherein the battery forecaster is further configured to estimate a remaining capacity change based on the remaining capacity and a previous remaining capacity associated with a previous effective power cycle, and wherein the data log further includes data indicating the remaining capacity change.

15. The system of claim 13, wherein the battery forecaster is further configured to estimate a cumulative remaining capacity change based on the remaining capacity and an initial capacity of the rechargeable battery, and wherein the data log further includes data indicating the cumulative remaining capacity change.

16. The system of claim 13, further comprising a display device coupled to the memory, wherein the display device is configured to display battery life and battery performance information based on the data log.

17. A non-transitory computer-readable storage device storing instructions that, when executed by a processor, cause the processor to perform operations comprising:
determining parameters of a rechargeable battery during an effective power cycle of the rechargeable battery, the parameters including a current provided by the rechargeable battery, a voltage across the rechargeable battery, and a temperature of the rechargeable battery, wherein the effective power cycle includes multiple charge operations and multiple discharge operations;
estimating a remaining capacity of the rechargeable battery based on the current, the voltage, and the temperature; and
generating an output indicating the remaining capacity.

18. The non-transitory computer-readable storage device of claim 17, wherein the operations further comprise:
comparing the remaining capacity to a threshold; and
estimating a second remaining capacity associated with a second effective power cycle in response to the remaining capacity exceeding the threshold.

19. The non-transitory computer-readable storage device of claim 17, wherein the operations further comprise:
receiving one or more initial values based on a user input prior to determining the current, the voltage, and the temperature; and
initializing battery parameters based on the one or more initial values, wherein the remaining capacity is estimated further based on the initial values.

20. The non-transitory computer-readable storage device of claim 19, wherein the one or more initial values include an initial reversible potential, an initial internal resistance, an initial capacity, an initial state of charge, a reference temperature, a battery temperature coefficient, a battery data sampling time step, an input error parameter, or a combination thereof.
